(19) United States
(12) Patent Application Publication
(10) Pub. No.: US 2026/0309811 A1
(43) Pub. Date: Oct. 8, 2026

(54) MAGNETIC MEASUREMENT DEVICE MANUFACTURING METHOD AND MAGNETIC MEASUREMENT DEVICE

(71) Applicant: KABUSHIKI KAISHA TOYOTA CHUO KENKYUSHO, Nagakute-shi, Aichi-ken (JP)

(72) Inventors: Jiaju MA, Nagakute-shi (JP); Norikazu OOTA, Nagakute-shi (JP); Takashi OZAKI, Nagakute-shi (JP); Minoru HIRANO, Nagakute-shi (JP); Masaru OGAWA, Nagakute-shi (JP)

(73) Assignee: KABUSHIKI KAISHA TOYOTA CHUO KENKYUSHO, Nagakute-shi, Aichi-ken (JP)

(21) Appl. No.: 19/480,701

(22) PCT Filed: Oct. 26, 2023
(86) PCT No.: PCT/JP2023/038617

§ 371 Date: Oct. 31, 2025

(30) Foreign Application Priority Data
May 26, 2023 (JP) 2023-086568

(51) Int. Cl. G01R 33/00

(52) U.S. Cl. CPC G01R 33/0052; G01R 33/0017

(57) ABSTRACT

Summary: [Problem] To provide a magnetic measurement device manufacturing method and a magnetic measurement device capable of improving sensing performance. [Solution] According to an embodiment of the present invention, a magnetic measurement device manufacturing method is provided. The method includes: in a preparation step, preparing a sensing wire having magnetic anisotropy, a sensing pickup coil wound around the sensing wire, a pulse generation circuit configured to supply a pulse current to the sensing wire, and a sensing circuit configured to measure, when a set sensing delay time has elapsed since supply of the pulse current started, an induced electromotive force for sensing generated in the sensing pickup coil by the pulse current. In a setting step, after supply of the pulse current starts, the sensing delay time is set to exclude a singular period in which the S/N ratio of the induced electromotive force for sensing is low.

### TECHNICAL FIELD

The present invention relates to a magnetic measurement device manufacturing method and a magnetic measurement device.

### BACKGROUND ART

As disclosed in PTL 1, NPL 1, and NPL 2, there has been known a magnetic measurement device including a wire having magnetic anisotropy, a pickup coil wound around the wire, a pulse generation circuit supplying a pulse current to the wire, and a sensing circuit measuring an induced electromotive force generated in the pickup coil.

In PTL 1, NPL 1, and NPL 2, improvement in the S/N ratio and/or reduction of low-frequency noise is achieved by peak-to-peak detection or a gradiometer method.

### CITATION LIST

### Patent Literature

PTL 1, Japanese Unexamined Patent Application Publication No. 2014-190774

### Non Patent Literature

NPL 1: J. Ma and T. Uchiyama,. “High Performance Single Element MI Magnetometer With Peak-to-Peak Voltage Detector by Synchronized Switching”, in IEEE Transactions on Magnetics, vol. 53, no. 11, pp. 1-4, November 2017, Art no. 4003404

NPL 2: J. Ma and T. Uchiyama, “Development of Peak-to-Peak Voltage Detector-Type MI Gradiometer for Magnetocardiography”, in IEEE Transactions on Magnetics, vol. 54, no. 11, pp. 1-5, November 2018, Art no. 5000605

### SUMMARY OF INVENTION

### Technical Problem

In the aforementioned magnetic measurement device using the wire, noise is generated during the magnetization process of the wire due to pinning sites such as scratches and impurities on the wire surface. In the vicinity of the peak of the induced electromotive force, there is a singular point where the S/N ratio becomes low due to this noise. Therefore, if the induced electromotive force is measured at this singular point, the sensing performance deteriorates.

In view of the above circumstances, the present invention provides a magnetic measurement device manufacturing method and a magnetic measurement device in which sensing performance is improved.

### Means for Solving Problems

According to one aspect of the present invention, a magnetic measurement device manufacturing method is provided. The manufacturing method includes the steps of:
a preparation step of preparing: a sensing wire having magnetic anisotropy; a sensing pickup coil wound around the sensing wire; a pulse generation circuit configured to supply a pulse current to the sensing wire; and a sensing circuit configured to measure a sensing induced electromotive force generated in the sensing pickup coil by the pulse current at a timing at which a set sensing delay time has elapsed since start of supply of the pulse current; and
a setting step of setting the sensing delay time such that a singular period during which an S/N ratio of the sensing induced electromotive force becomes low is excluded after the start of the supply of the pulse current.

According to such an aspect, since the sensing induced electromotive force is measured after the singular period during which a singular point is observed has passed, it is possible to obtain a magnetic measurement device capable of outputting a signal with a high S/N ratio. Therefore, the sensing performance of the magnetic measurement device is enhanced.

### BRIEF DESCRIPTION OF DRAWINGS

FIG. 1 is a schematic circuit diagram of a magnetic measurement device 1A of a first embodiment.

FIG. 2 is a graph illustrating the waveform of an induced electromotive force in a sensing pickup coil 3 (upper part), and the waveform of an excitation pulse current supplied to a sensing wire 2 (lower part).

FIG. 3 is a graph illustrating an example of the relationship between an external magnetic field, and first peak values in an excitation stage and second peak values in a recovery stage.

FIG. 4 is a schematic circuit diagram of a manufacturing device 200 for a magnetic measurement device.

FIG. 5 includes graphs each illustrating an example of the S/N ratio in the measurement results of the induced electromotive force generated in the sensing pickup coil 3.

FIG. 6 is a schematic circuit diagram of a magnetic measurement device 1B of a second embodiment.

FIG. 7 is a graph comparing the noise spectrum of a conventional magnetic measurement device and that of the magnetic measurement device 1B.

FIG. 8 is a graph illustrating an example of the S/N ratio in the magnetic measurement device 1B.

### DETAILED DESCRIPTION

Hereinafter, embodiments of the present invention will be described using the drawings. Various features discussed in the following embodiments can be combined with each other.

### First Embodiment

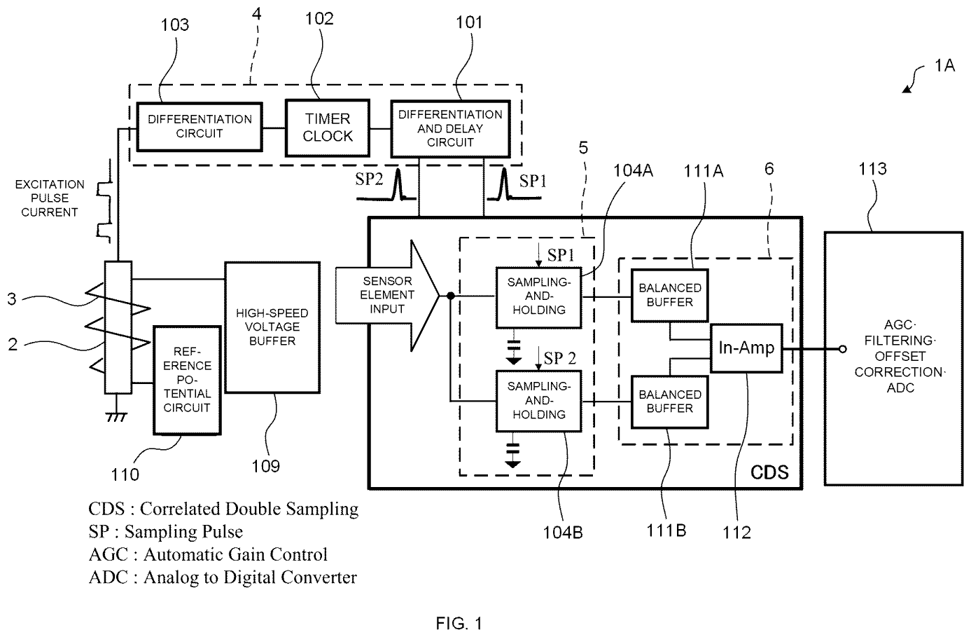

FIG. 1 is a schematic circuit diagram of a magnetic measurement device 1A of a first embodiment. The magnetic measurement device 1A includes a sensing wire 2, a sensing pickup coil 3, a pulse generation circuit 4, a sensing circuit 5, and a time differential circuit 6.

### <Sensing Wire 2>

The sensing wire 2 is an element having magnetic anisotropy. The sensing wire 2 is configured such that its impedance changes due to a skin effect caused by a pulse current and an external magnetic field. For example, an amorphous wire having a three-layer domain structure can be used as the sensing wire 2.

### <Sensing Pickup Coil 3>

The sensing pickup coil 3 is wound around the sensing wire 2. Specifically, the sensing pickup coil 3 is a solenoid-shaped coil that detects the magnetic field around the sensing wire 2. An induced electromotive force is generated in the sensing pickup coil 3 due to the skin effect of the sensing wire 2.

### <Pulse Generation Circuit 4>

The pulse generation circuit 4 is configured to supply a pulse current to the sensing wire 2 to excite the sensing wire 2. The pulse generation circuit 4 includes a differentiation and delay circuit 101, a timer clock 102, and a differentiation circuit 103.

### <Sensing Circuit 5>

The sensing circuit 5 is configured to measure a sensing induced electromotive force generated in the sensing pickup coil 3 by a pulse current supplied by the sensing wire 2 at a timing at which a set sensing delay time has elapsed since the start of the supply of the pulse current. The sensing delay time is set such that a singular period during which the S/N ratio of the sensing induced electromotive force becomes low is excluded after the start of the supply of the pulse current.

The sensing circuit 5 has a first detection circuit including a first sample-and-hold circuit 104A and a second detection circuit including a second sample-and-hold circuit 104B.

The first detection circuit is configured to measure the sensing induced electromotive force generated in the sensing pickup coil 3 by the pulse current at a timing at which a preset first delay time has elapsed since the start of the supply of the pulse current.

The second detection circuit is configured to measure the sensing induced electromotive force generated in the sensing pickup coil 3 by the pulse current at a timing at which a second delay time, which is longer than the first delay time, has elapsed since the start of the supply of the pulse current. That is, the second detection circuit measures the sensing induced electromotive force at a timing later than that of the first detection circuit.

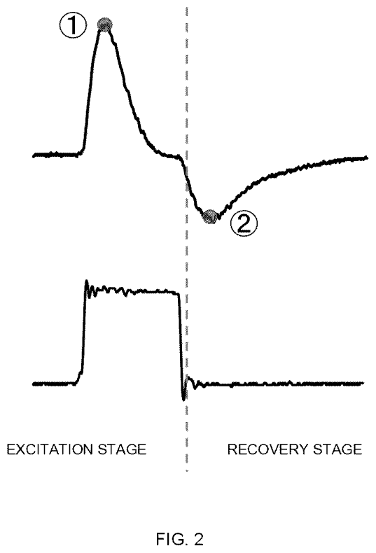

Here, the induced electromotive force generated in the sensing pickup coil 3 will now be described. FIG. 2 is a graph illustrating the waveform of the induced electromotive force in the sensing pickup coil 3 (upper part) and the waveform of the excitation pulse current supplied to the sensing wire 2 (lower part). In each of the excitation stage, where the sensing pickup coil 3 is induced by the rising edge of the pulse current, and the recovery stage, where the sensing pickup coil 3 is induced by the falling edge of the pulse current, the induced electromotive force exhibits a peak value. The first peak value in the excitation stage (circled number 1 in the graph) and the second peak value in the recovery stage (circled number 2 in the graph) have opposite voltage polarities.

The first delay time is set in accordance with the excitation stage. In other words, the first delay time is set such that the first detection circuit measures the induced electromotive force in the excitation stage. The second delay time is set in accordance with the recovery stage. In other words, the second delay time is set such that the second detection circuit measures the induced electromotive force in the recovery stage. The first delay time and the second delay time are each on the order of ns (nanoseconds).

As illustrated in FIG. 1, a sampling pulse current SP1, whose peak timing is adjusted by the first delay time, is input to the first detection circuit (first sample-and-hold circuit 104A). In other words, in the first detection circuit, a signal is sampled and held at the peak timing of the sampling pulse current SP1. A sampling pulse current SP2, whose peak timing is adjusted by the second delay time, is input to the second detection circuit (second sample-and-hold circuit 104B). In other words, in the second detection circuit, a signal is sampled and held at the peak timing of the sampling pulse current SP2.

The first detection circuit and the second detection circuit receive input of the sampling pulse currents SP1 and SP2 from the differentiation and delay circuit 101 and obtain sample values (i.e., sensing induced electromotive force). The differentiation and delay circuit 101 (specifically, the memory area of the circuit) stores the sensing delay times (i.e., the first delay time and the second delay time) set by a later-described procedure, and a singular period (i.e., a timing at which a singular point occurs). The differentiation and delay circuit 101 outputs the sampling pulse currents SP1 and SP2 having peaks immediately after the respective sensing delay times have elapsed.

A signal due to the induced electromotive force generated in the sensing pickup coil 3 is sent to the first detection circuit and the second detection circuit via a high-speed voltage buffer 109. The high-speed voltage buffer 109 is provided to block interference between the sensing pickup coil 3 and the pulse generation circuit 4, and the sensing circuit 5. A reference potential circuit 110 is connected to the sensing pickup coil 3.

### <Time Differential Circuit 6>

The time differential circuit 6 is configured to calculate the difference between the sensing induced electromotive force measured by the first detection circuit and the sensing induced electromotive force measured by the second detection circuit. The time differential circuit 6 detects the time difference using correlated double sampling (CDS). The time differential circuit 6 includes a first balanced buffer 111A, a second balanced buffer 111B, and an instrumentation amplifier 112.

The sensing induced electromotive force in the excitation stage, output by the first detection circuit (first sample-and-hold circuit 104A), and the sensing induced electromotive force in the recovery stage, output by the second detection circuit (second sample-and-hold circuit 104B), are input to the instrumentation amplifier 112 via the first balanced buffer 111A and the second balanced buffer 111B, respectively.

The instrumentation amplifier 112 outputs the difference between the sensing induced electromotive force in the excitation stage and the sensing induced electromotive force in the recovery stage. The output of the instrumentation amplifier 112 is input to a function circuit 113. The function circuit 113 performs processing such as AGC (automatic gain control), filtering, offset correction, and ADC (analog-to-digital conversion) to output a voltage value (measurement signal) corresponding to the magnetism sensed by the sensing wire 2.

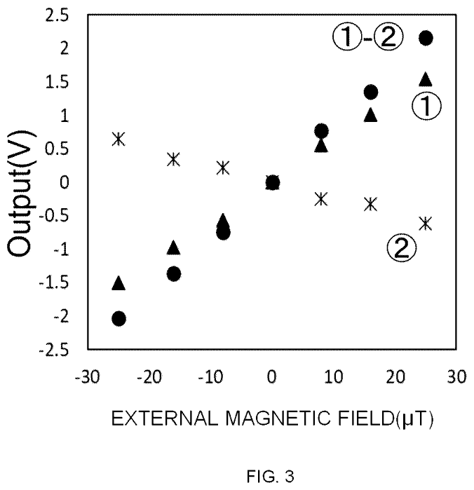

FIG. 3 is a graph illustrating an example of the relationship between the external magnetic field, and the first peak values in the excitation stage and the second peak values in the recovery stage. The first peak values (triangular points in the graph) detected by the first detection circuit and the second peak values (star-shaped points in the graph) detected by the second detection circuit are differential-mode signal values that depend on the magnitude of the external magnetic field. The differences (circular points in the graph) between the first and second peak values exhibit strong linearity with respect to the external magnetic field. Therefore, by taking the time difference of the sensing induced electromotive force using the time differential circuit 6, the accuracy of the magnetic measurement can be enhanced.

### <Manufacturing Method for Magnetic Measurement Device 1A>

The manufacturing method for the magnetic measurement device 1A includes a preparation step, a setting step, and an assembly step.

In the preparation step, the sensing wire 2, the sensing pickup coil 3, the pulse generation circuit 4, the sensing circuit 5, and the time differential circuit 6 are prepared.

In the setting step, the sensing delay time is set such that a singular period during which the S/N ratio of the sensing induced electromotive force, measured by the sensing circuit 5, becomes low is excluded after the start of the supply of the pulse current by the pulse generation circuit 4. Accordingly, since the sensing induced electromotive force is measured after the singular period during which a singular point is observed has passed, the magnetic measurement device 1A capable of outputting a signal with a high S/N ratio is achieved. Therefore, the sensing performance of the magnetic measurement device 1A is enhanced.

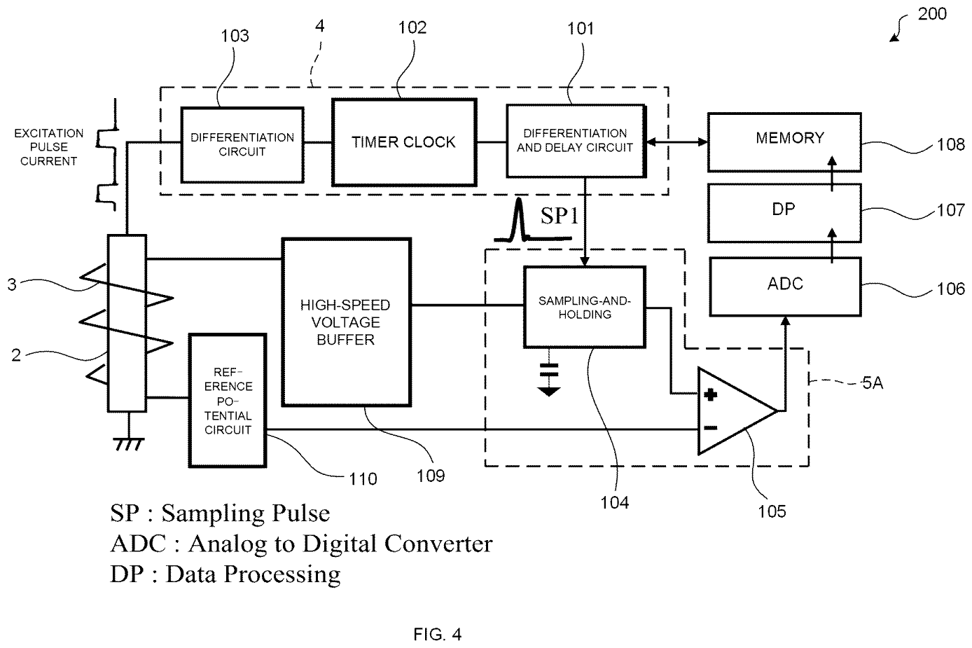

FIG. 4 is a schematic circuit diagram of the manufacturing device 200 for the magnetic measurement device. The manufacturing device 200 is a device that automatically tunes the sensing delay time (i.e., detection timing) of the magnetic measurement device 1A. The manufacturing device 200 incorporates the sensing wire 2, the sensing pickup coil 3, the pulse generation circuit 4, and an adjustment sensing circuit 5A. The sensing wire 2, the sensing pickup coil 3, and the pulse generation circuit 4 are those used in the magnetic measurement device 1A (i.e., those prepared in the preparation step).

The adjustment sensing circuit 5A includes a sample-and-hold circuit 104 and an operational amplifier 105. The adjustment sensing circuit 5A receives input of the sampling pulse current SP1 from the differentiation and delay circuit 101 and obtains sample values (i.e., sensing induced electromotive force). The differentiation and delay circuit 101 reads an adjustment measurement time stored in a memory 108 and outputs the sampling pulse current SP1 having its peak immediately after the adjustment measurement time has elapsed.

In the sample-and-hold circuit 104, a signal is sampled and held at the peak timing of the sampling pulse current SP1. In the operational amplifier 105, the sampled and held signal is input to the non-inverting input, while the signal from the reference potential circuit 110, which is connected to the sensing pickup coil 3, is input to the inverting input. The output signal amplified by the operational amplifier 105 is input to an analog-to-digital conversion circuit 106.

The signal digitized by the analog-to-digital conversion circuit 106 is input to a data processing unit 107. The data processing unit 107 calculates the S/N ratio (ratio of signal to noise) of the sample values. The data processing unit 107 determines the sensing delay time through a search procedure described later. The data processing unit 107 also writes the set sensing delay time to the memory 108. The memory 108 stores not only the sensing delay time but also the singular period used in determining the sensing delay time

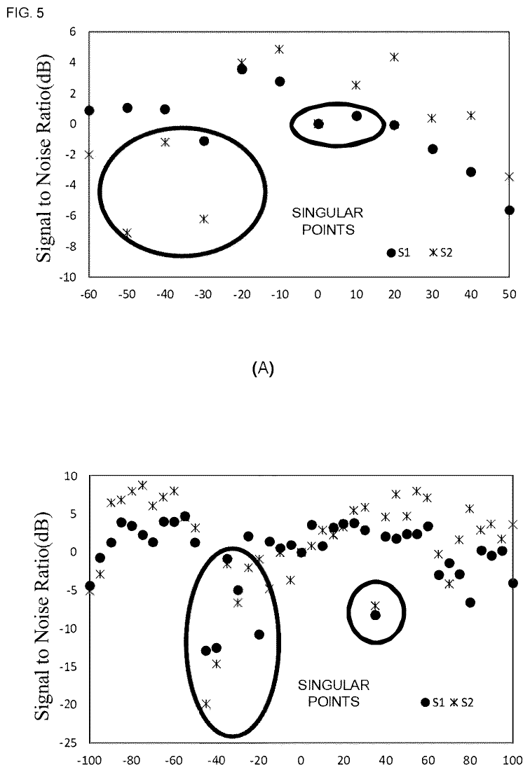

Here, a description is provided regarding the singular period in which the S/N ratio becomes low during the measurement of the induced electromotive force. FIG. 5 includes graphs each illustrating an example of the S/N ratio in the measurement results of the induced electromotive force generated in the sensing pickup coil 3. The graph in FIG. 5A indicates the measurement results during the excitation stage, while the graph in FIG. 5B indicates the measurement results during the recovery stage

Each graph shows measurement results for two samples, S1 and S2, of the sensing wire 2. The horizontal axis of each graph represents time (unit: ns), with 0 ns indicating the time at which the first or second peak value is observed. The vertical axis represents the S/N ratio (unit: dB), with the S/N ratio at 0 ns defined as 0 dB. When the S/N ratio is positive, the detection sensitivity is higher than that at the peak value; and when the S/N ratio is negative, the detection sensitivity is lower than that at the peak value.

The S/N ratio of each graph includes singular points where the S/N ratio is low. If signal measurement is performed at such singular points, the accuracy of the magnetic measurement deteriorates. Therefore, in the setting step, the “sensing delay time” is set so as to avoid measurements during the “singular period” in which such singular points may occur. Note that a “singular point” refers to a point where the S/N ratio is 90% or less compared to the average S/N ratio measured during a search period for the sensing delay time (before the measurement start time for the induced electromotive force is determined) in the setting step.

In the setting step, the sensing delay time is determined by measuring the S/N ratio while varying the time from the start of the supply of the pulse current to the measurement of the sensing induced electromotive force, in an environment where a constant magnetic field is applied to the sensing wire 2. In detail, the manufacturing device 200 repeatedly acquires voltages based on the shape (i.e., delay time) of the sampling pulse current adjusted by the differentiation and delay circuit 101, and calculates the S/N ratio of the acquired voltages, until a delay time that does not include a singular point is found. In other words, the manufacturing device 200 searches for an induced electromotive force measurement start time that does not have any nearby singular points. This enables the appropriate setting of a sensing delay time that can avoid deterioration in measurement accuracy.

In the setting step, the S/N ratio is measured during a search period that includes the timing at which the peak value of the sensing induced electromotive force is observed, and during which the sensing induced electromotive force having an absolute value greater than or equal to a predetermined threshold may be observed. The threshold may be set to, for example, 50%, 45%, 40%, 35%, or 30% of the peak value. The “search period” is a period predicted based on the peak value observation timing and the characteristics of the sensing wire 2. By pre-setting the search period for measuring the S/N ratio in such a way, the search period for determining the sensing delay time by the manufacturing device 200 is reduced. As a result, the manufacturing cost of the magnetic measurement device 1A is lowered.

Furthermore, in the setting step, the sensing delay time is set such that the timing at which the sensing induced electromotive force is measured is at least 10 nsec later than the timing at which the S/N ratio that is less than or equal to a certain value is measured. For example, if a low S/N ratio (singular point) is measured during the search for the sensing delay time, the next S/N ratio measurement timing is set to be at least 10 nsec later. This reduces the search period for the sensing delay time and lowers the manufacturing cost of the magnetic measurement device 1A.

The manufacturing device 200 writes the sensing delay time, determined by the aforementioned procedure, to the memory 108. The sensing delay time stored in the memory 108 is incorporated into the differentiation and delay circuit 101 to complete the magnetic measurement device 1A.

In the setting step, a first delay time and a second delay time are each set as the sensing delay time. In other words, the manufacturing device 200 independently performs a process of determining the first delay time in the excitation stage and a process of determining the second delay time in the recovery stage. For example, after a search for the first delay time is performed for the sensing pickup coil 3, a search for the second delay time is performed.

In the assembly step, the circuits that constitute the magnetic measurement device 1A are assembled after the sensing delay time has been set. The magnetic measurement device 1A incorporates two mutually independent parameters, the first delay time and the second delay time, as the sensing delay time. As a result, the magnetic measurement device 1A with enhanced accuracy is achieved through the avoidance of singular points and correlated double sampling.

Specifically, since the outputs during the excitation stage and the recovery stage constitute common-mode signals, correlated double sampling can significantly reduce common-mode noise, such as thermal noise (kTC noise) caused by parasitic capacitance at the detection node and during sampling and holding, as well as magnetic thermal noise from the magnetic material element. In addition, time-differential measurement on the nanosecond scale enables significant suppression of low-frequency noise, including 1/f noise, voltage fluctuation noise at the coil terminals, and electromagnetic interference noise.

### Second Embodiment

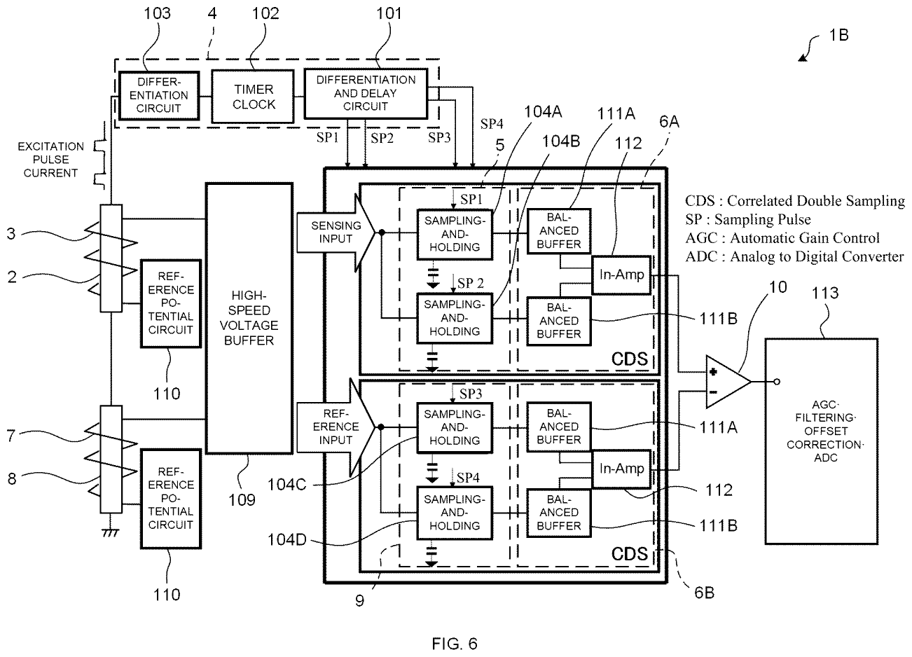

FIG. 6 is a schematic circuit diagram of a magnetic measurement device 1B of a second embodiment. The magnetic measurement device 1B includes the sensing wire 2, the sensing pickup coil 3, the pulse generation circuit 4, the sensing circuit 5, a first time differential circuit 6A, a second time differential circuit 6B, a reference wire 7, a reference pickup coil 8, a reference circuit 9, and an output differential circuit 10.

The magnetic measurement device 1B is a gradiometer-type measurement device including a pair of sensor elements and a circuit that outputs the spatial difference of the output signals of these elements. Because the sensing wire 2, sensing pickup coil 3, pulse generation circuit 4, and sensing circuit 5 of the magnetic measurement device 1B are the same as those of the magnetic measurement device 1A of the first embodiment, their descriptions are omitted.

### <Time Differential Circuit 6A and 6B>

The first time differential circuit 6A is the same as the time differential circuit 6 of the first embodiment of the magnetic measurement device 1A. The second time differential circuit 6B is configured to calculate the difference between a reference induced electromotive force measured by a third detection circuit (third sample-and-hold circuit 104C) of the reference circuit 9 and the reference induced electromotive force measured by a fourth detection circuit (fourth sample-and-hold circuit 104D). The principle and configuration of the second time differential circuit 6B are the same as those of the first time differential circuit 6A.

### <Reference Wire 7>

The reference wire 7 is an element having magnetic anisotropy. The reference wire 7 is equivalent to the sensing wire 2. The reference wire 7 is connected in series with the sensing wire 2. Therefore, the excitation pulse current generated by the pulse generation circuit 4 is also supplied to the reference wire 7 via the sensing wire 2.

### <Reference Pickup Coil 8>

The reference pickup coil 8 is wound around the reference wire 7. The reference pickup coil 8 is equivalent to the sensing pickup coil 3.

### <Reference Circuit 9>

The reference circuit 9 is configured to measure a reference induced electromotive force generated in the reference pickup coil 8 by a pulse current for exciting the sensing wire 2 and the reference ire 7 at a timing at which a set reference delay time has elapsed since the start of the supply of the pulse current.

The reference circuit 9 has the third detection circuit including the third sample-and-hold circuit 104C and the fourth detection circuit including the fourth sample-and-hold circuit 104D.

The third detection circuit is configured to measure the reference induced electromotive force generated in the reference pickup coil 8 by the pulse current at a timing at which a preset third delay time has elapsed since the start of the supply of the pulse current. Note that the third delay time in the reference circuit 9 is different from the first delay time in the sensing circuit 5. In other words, the first delay time and the third delay time are independent of each other.

The fourth detection circuit is configured to measure the sensing induced electromotive force generated in the reference pickup coil 8 by the pulse current at a timing at which a preset fourth delay time, which is longer than the third delay time, has elapsed since the start of the supply of the pulse current. That is, the fourth detection circuit measures the reference induced electromotive force at a timing later than that of the third detection circuit. Note that the fourth delay time in the reference circuit 9 is different from the second delay time in the sensing circuit 5. In other words, the second delay time and the fourth delay time are independent of each other.

The third delay time in the reference circuit 9 is set such that the third detection circuit measures the induced electromotive force in the excitation stage. The fourth delay time in the reference circuit 9 is set such that the fourth detection circuit measures the induced electromotive force in the recovery stage.

A sampling pulse current SP3, whose peak timing is adjusted by the third delay time, is input to the third detection circuit (third sample-and-hold circuit 104C) of the reference circuit 9. A sampling pulse current SP4, whose peak timing is adjusted by the fourth delay time, is input to the fourth detection circuit (fourth sample-and-hold circuit 104D) of the reference circuit 9.

### <Output Differential Circuit 10>

The output differential circuit 10 is configured to calculate the difference between the sensing induced electromotive force and the reference induced electromotive force.

Specifically, the output differential circuit 10 is a differential amplifier that receives the output of the first time differential circuit 6A (time difference in the sensing circuit 5) at its non-inverting input, and the output of the second time differential circuit 6B (time difference in the reference circuit 9) at its inverting input. The output differential circuit 10 has an analog filter and an offset compensation circuit. The output of the output differential circuit 10 is input to the function circuit 113.

### <Manufacturing Method for Magnetic Measurement Device 1B>

The manufacturing method for the magnetic measurement device 1B includes a preparation step, a setting step, and an assembly step.

In the preparation step, the sensing wire 2, sensing pickup coil 3, pulse generation circuit 4, sensing circuit 5, first time differential circuit 6A, second time differential circuit 6B, reference wire 7, reference pickup coil 8, reference circuit 9, and output differential circuit 10 are prepared.

The setting step is the same as the setting step of the manufacturing method for the magnetic measurement device 1A, except for the following points. That is, in the setting step of the manufacturing method for the magnetic measurement device 1B, the reference delay time is set such that a singular period during which the S/N ratio of the reference induced electromotive force becomes low is excluded after the start of the supply of the pulse current.

The reference delay time includes, as mentioned above, the third delay time in the third detection circuit of the reference circuit 9 and the fourth delay time in the fourth detection circuit. The determination of the reference delay time is performed by replacing the sensing wire 2 and the sensing pickup coil 3 of the manufacturing device 200 with the reference wire 7 and the reference pickup coil 8.

Like the sensing delay time, the third delay time and the fourth delay time for the reference delay time are determined independently of each other. Thus, in the setting step, four time parameters are set: the first and second delay times as sensing delay times, and the third and fourth delay times as reference delay times.

In the assembly step, the circuits constituting the magnetic measurement device 1A are assembled after the sensing delay time and reference delay time are set. As a result, the magnetic measurement device 1B with enhanced accuracy is achieved through canceling of the environmental magnetic noise, in addition to the avoidance of singular points and correlated double sampling.

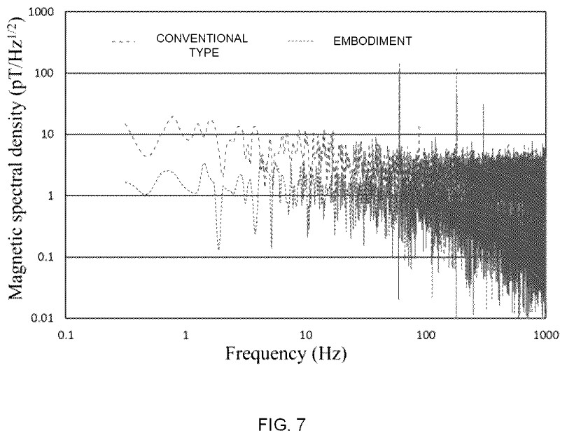

FIG. 7 is a graph comparing the noise spectrum of a conventional magnetic measurement device and that of the magnetic measurement device 1B. In FIG. 7, the horizontal axis represents noise frequency, while the vertical axis represents the density of the magnetic spectrum detected by the device. In the conventional type, the density is about 10 pT/Hz^{1/2} at 1 Hz and about 8 pT/Hz^{1/2} at 10 Hz. In contrast, the magnetic measurement device 1B achieves about 3 pT/Hz^{1/2} at 1 Hz and about 3 pT/Hz^{1/2} at 10 Hz, demonstrating a significant reduction in low-frequency noise.

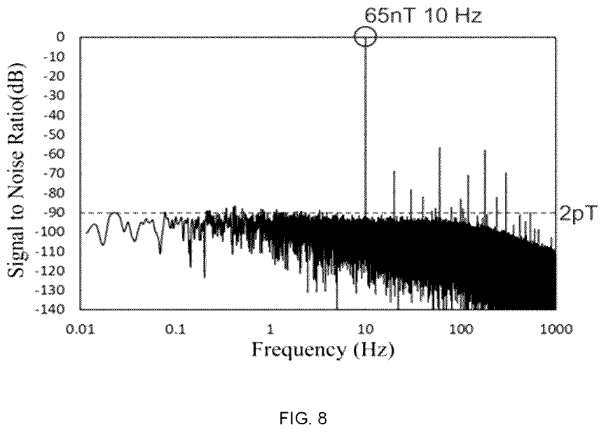

FIG. 8 is a graph illustrating an example of the S/N ratio in the magnetic measurement device 1B. Utilizing a Helmholtz coil, a target signal (65 nT, 10 Hz) was applied, and the S/N ratio was measured. For the target signal, the noise floor of the magnetic measurement device 1B was about −90 dB (for a 65 nT signal, −90 dB corresponds to about 2 pT). Therefore, the magnetic measurement device 1B can also be applied to the measurement of biomagnetism at the pT level.

Although the embodiments of the present invention have been described above, the present invention is not limited thereto, and may be modified as appropriate without departing from the technical spirit of the invention.

The magnetic measurement device of the present invention does not necessarily have to include a time differential circuit. For example, the magnetic measurement device may acquire only the induced electromotive force in the excitation stage. That is, the magnetic measurement device of the present invention may have a configuration in which the function circuit 113 is directly connected to the sensing circuit 5 and/or the reference circuit 9.

The magnetic measurement device of the present invention may also be configured to allow the user to rewrite (re-set) each of the delay times.

The above-described embodiments may be provided in the following modes.
(1) A magnetic measurement apparatus manufacturing method comprising the steps of: a preparation step of preparing: a sensing wire having magnetic anisotropy; a sensing pickup coil wound around the sensing wire; a pulse generation circuit configured to supply a pulse current to the sensing wire; and a sensing circuit configured to measure a sensing induced electromotive force generated in the sensing pickup coil by the pulse current at a timing at which a set sensing delay time has elapsed since start of supply of the pulse current; and a setting step of setting the sensing delay time such that a singular period during which an S/N ratio of the sensing induced electromotive force becomes low is excluded after the start of the supply of the pulse current.
(2) The magnetic measurement apparatus manufacturing method according to (1), wherein: in the setting step, the sensing delay time is determined by measuring the S/N ratio while varying time from the start of the supply of the pulse current to measurement of the sensing induced electromotive force, in an environment where a constant magnetic field is applied to the sensing wire.
(3) The magnetic measurement apparatus manufacturing method according to (2), wherein: in the setting step, the S/N ratio is measured during a period that includes a timing at which a peak value of the sensing induced electromotive force is observed, and during which the sensing induced electromotive force having an absolute value greater than or equal to a predetermined threshold may be observed.
(4) The magnetic measurement apparatus manufacturing method according to claim 2 or (3), wherein: in the setting step, the sensing delay time is set such that a timing at which the sensing induced electromotive force is measured is at least 10 nsec later than a timing at which the S/N ratio that is less than or equal to a certain value is measured.
(5) The magnetic measurement apparatus manufacturing method according to any one of (1) to (4), wherein: the sensing circuit includes: a first detection circuit that measures the sensing induced electromotive force at a timing at which a first delay time has elapsed; and a second detection circuit that measures the sensing induced electromotive force at a timing at which a second delay time, which is longer than the first delay time, has elapsed; in the preparation step, a time differential circuit configured to calculate a difference between the sensing induced electromotive force measured by the first detection circuit and the sensing induced electromotive force measured by the second detection circuit is further prepared; and in the setting step, the first delay time and the second delay time are each set as the sensing delay time.
(6) The magnetic measurement apparatus manufacturing method according to any one of (1) to (5), wherein: in the preparing step, further preparing: a reference wire having magnetic anisotropy; a reference pickup coil wound around the reference wire; a reference circuit configured to measure a reference induced electromotive force generated in the reference pickup coil by the pulse current at a timing at which a set reference delay time has elapsed since the start of the supply of the pulse current; and an output differential circuit configured to calculate a difference between the sensing induced electromotive force and the reference induced electromotive force; and in the setting step, the reference delay time is set such that a singular period during which an S/N ratio of the reference induced electromotive force becomes low is excluded after the start of the supply of the pulse current.
(7) A magnetic measurement apparatus comprising: a sensing wire having magnetic anisotropy; a sensing pickup coil wound around the sensing wire; a pulse generation circuit configured to supply a pulse current to the sensing wire; and a sensing circuit configured to measure a sensing induced electromotive force generated in the sensing pickup coil by the pulse current at a timing at which a set sensing delay time has elapsed since start of supply of the pulse current, wherein the sensing delay time is set such that a singular period during which an S/N ratio of the sensing induced electromotive force becomes low is excluded after the start of the supply of the pulse current.
(8) The magnetic measurement apparatus according to (7), wherein: the singular period is stored.

Of course, the above are not the only possible implementations.

Finally, although various embodiments of the present disclosure have been described, these are presented merely as examples and are not intended to limit the scope of the invention. The novel embodiments may be implemented in various other forms, and various omissions, substitutions, and changes can be made without departing from the gist of the invention. Such embodiments and their modifications are included within the scope and gist of the invention, and also within the scope of the invention as defined in the claims and their equivalents.

### REFERENCE SIGNS LIST

1A: magnetic measurement device
1B: magnetic measurement device
2: sensing wire
3: sensing pickup coil
4: pulse generation circuit
5: sensing circuit
5A: adjustment sensing circuit
6: time differential circuit
6A: first time differential circuit
6B: second time differential circuit
7: reference wire
8: reference pickup coil
9: reference circuit
10: output differential circuit
101: delay circuit
102: timer clock
103: differentiation circuit
104: sample-and-hold circuit
104A: first sample-and-hold circuit
104B: second sample-and-hold circuit
104C: third sample-and-hold circuit
104D: fourth sample-and-hold circuit
105: operational amplifier
106: analog-to-digital conversion circuit
107: data processing unit
108: memory
109: high-speed voltage buffer
110: reference potential circuit
111A: first balanced buffer
111B: second balanced buffer
112: instrumentation amplifier
113: function circuit
200: manufacturing device

What is claimed is:

1. A magnetic measurement apparatus manufacturing method comprising:
preparing:
a sensing wire having magnetic anisotropy;
a sensing pickup coil wound around the sensing wire;
a pulse generation circuit configured to supply a pulse current to the sensing wire; and
a sensing circuit configured to measure a sensing induced electromotive force generated in the sensing pickup coil by the pulse current at a timing at which a set sensing delay time has elapsed since start of supply of the pulse current; and
setting the sensing delay time such that a singular period during which an S/N ratio of the sensing induced electromotive force becomes low is excluded after the start of the supply of the pulse current.

2. The magnetic measurement apparatus manufacturing method according to claim 1, wherein:
in the setting, the sensing delay time is determined by measuring the S/N ratio while varying time from the start of the supply of the pulse current to measurement of the sensing induced electromotive force, in an environment where a constant magnetic field is applied to the sensing wire.

3. The magnetic measurement apparatus manufacturing method according to claim 2, wherein:
in the setting, the S/N ratio is measured during a period that includes a timing at which a peak value of the sensing induced electromotive force is observed, and during which the sensing induced electromotive force having an absolute value greater than or equal to a predetermined threshold may be observed.

4. The magnetic measurement apparatus manufacturing method according to claim 2, wherein:
in the setting, the sensing delay time is set such that a timing at which the sensing induced electromotive force is measured is at least 10 nsec later than a timing at which the S/N ratio that is less than or equal to a certain value is measured.

5. The magnetic measurement apparatus manufacturing method according to claim 1, wherein:
the sensing circuit includes:
a first detection circuit that measures the sensing induced electromotive force at a timing at which a first delay time has elapsed; and
a second detection circuit that measures the sensing induced electromotive force at a timing at which a second delay time, which is longer than the first delay time, has elapsed;
in the preparing, a time differential circuit configured to calculate a difference between the sensing induced electromotive force measured by the first detection circuit and the sensing induced electromotive force measured by the second detection circuit is further prepared; and
in the setting, the first delay time and the second delay time are each set as the sensing delay time.

6. The magnetic measurement apparatus manufacturing method according to claim 1, wherein:
in the preparing, further preparing:
a reference wire having magnetic anisotropy;
a reference pickup coil wound around the reference wire;
a reference circuit configured to measure a reference induced electromotive force generated in the reference pickup coil by the pulse current at a timing at which a set reference delay time has elapsed since the start of the supply of the pulse current; and
an output differential circuit configured to calculate a difference between the sensing induced electromotive force and the reference induced electromotive force; and
in the setting, the reference delay time is set such that a singular period during which an S/N ratio of the reference induced electromotive force becomes low is excluded after the start of the supply of the pulse current.

7. A magnetic measurement apparatus comprising:
a sensing wire having magnetic anisotropy;
a sensing pickup coil wound around the sensing wire;
a pulse generation circuit configured to supply a pulse current to the sensing wire; and
a sensing circuit configured to measure a sensing induced electromotive force generated in the sensing pickup coil by the pulse current at a timing at which a set sensing delay time has elapsed since start of supply of the pulse current,
wherein the sensing delay time is set such that a singular period during which an S/N ratio of the sensing induced electromotive force becomes low is excluded after the start of the supply of the pulse current.

8. The magnetic measurement apparatus according to claim 7, wherein:
the singular period is stored.
